(19) United States
(12) Patent Application Publication
(10) Pub. No.: US 2026/0239732 A1
(43) Pub. Date: Aug. 13, 2026

(54) SEMICONDUCTOR STRUCTURE AND METHODS OF FORMING THE SAME

(71) Applicant: Taiwan Semiconductor Manufacturing Co., Ltd., Hsinchu (TW)

(72) Inventors: Pei-Yu Chou, Hsinchu (TW); Ting Ying Wu, Hsinchu (TW); Meng-Ku Chen, New Taipei City (TW)

(21) Appl. No.: 19/280,983

(22) Filed: Jul. 25, 2025

Related U.S. Application Data
(60) Provisional application No. 63/757,471, filed on Feb. 12, 2025.

(51) Int. Cl. H10D 84/85; H01L 23/00; H01L 23/522; H01L 23/528; H10D 30/00; H10D 62/10

(52) U.S. Cl. CPC H10D 84/851; H10D 30/502; H10D 62/121; H10W 20/427; H10W 20/435; H10W 20/498; H10W 42/121; H10W 80/327; H10W 90/794

(57) ABSTRACT

A method includes forming nanostructures over a semiconductor substrate; forming a front-side interconnect structure over a front-side of the nanostructures; directly bonding a first side of a carrier substrate to the front-side interconnect structure using a dielectric-to-dielectric bonding process; depositing a dielectric layer on a second side of the carrier substrate; and forming a back-side interconnect structure over a back-side of the nanostructures. In an embodiment, the dielectric layer provides a tensile stress.

### PRIORITY CLAIM AND CROSS-REFERENCE

This application claims the benefit of the following provisionally filed U.S. patent application: Application No. 63/757,471, filed on Feb. 12, 2025, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor, in accordance with some embodiments.

FIGS. 2, 3, 4, 5, 6, and 7 illustrate cross-sectional views of intermediate stages in the manufacturing of stacking transistors, in accordance with some embodiments.

FIGS. 8, 9, and 10 illustrate cross-sectional views of intermediate stages in the formation of a warpage control layer, in accordance with some embodiments.

FIG. 11 illustrates a cross-sectional view of an intermediate stage in the formation of a warpage control layer, in accordance with some embodiments.

FIG. 12 illustrates a cross-sectional view of an intermediate stage in the formation of a warpage control layer, in accordance with some embodiments.

FIGS. 13, 14, 15, and 16 illustrate cross-sectional views of intermediate stages in the manufacturing of a back-side interconnect structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A warpage control layer on a device structure and methods of forming the same are provided. The warpage control layer is formed on a carrier substrate to provide structural support and reduce warpage. For example, the warpage control layer may include a tensile dielectric layer formed on the outer side of the carrier substrate. The warpage control layer may be deposited on the carrier substrate before or after bonding the carrier substrate to the device. The warpage control layer reduces warpage, which can improve device processing and reliability. In some cases, a warpage control layer may reduce warpage in a device structure that includes features such as stacking transistors or power rails, though a warpage control layer as described herein may be utilized for any suitable device structure.

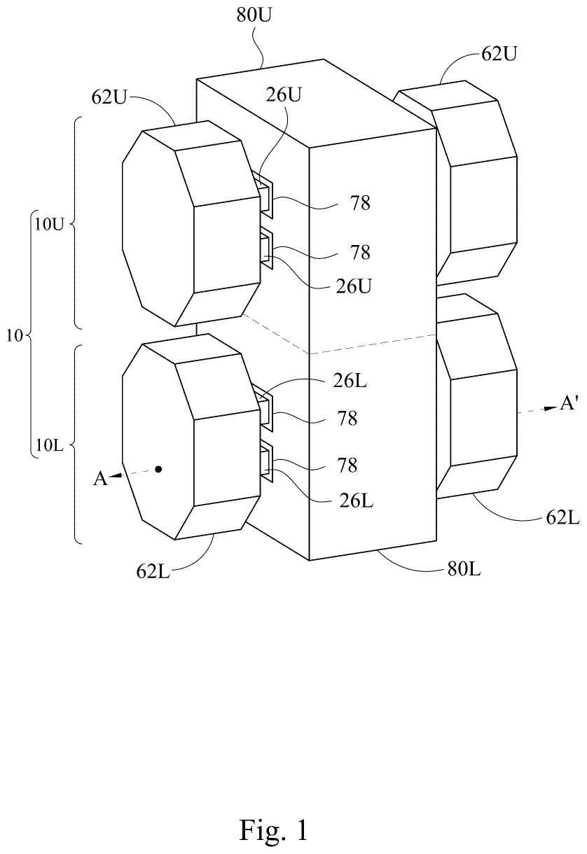

FIG. 1 illustrates an example of a stacking transistor 10 (including FETs (Field-Effect Transistors) 10U and 10L) in accordance with some embodiments. FIG. 1 is a three-dimensional view, and some features of the stacking transistor 10 are omitted for illustration clarity.

The stacking transistor 10 includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., FinFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

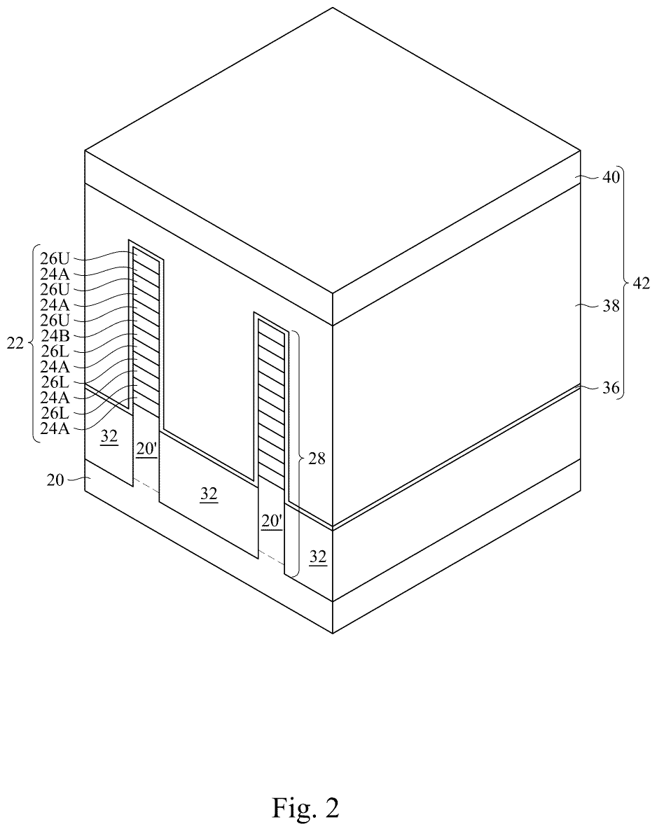

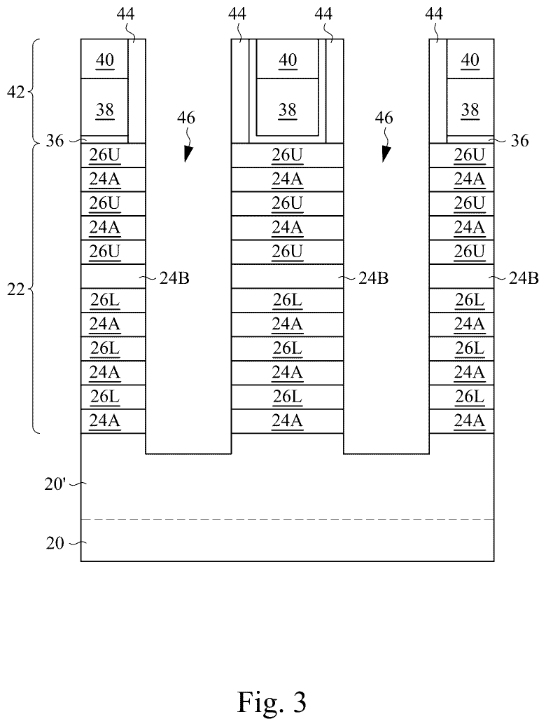

FIG. 1 further illustrates a reference cross-section that is used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Subsequent figures may refer to this reference cross-sections for clarity. FIGS. 2 through 16 illustrate intermediate stages in the formation of a device structure comprising stacking transistors (as schematically represented in FIG. 1) in accordance with some embodiments. FIGS. 3 through 16 illustrate vertical cross-sectional views along a similar cross-section as vertical reference cross-section A-A′ in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof. In some cases, multiple stacking transistors 10 may be formed on a same wafer or substrate 20. In some cases, the wafer or substrate 20 may be subsequently singulated to form multiple dies or multiple devices.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy semiconductor nanostructures 24A are formed of or comprise silicon germanium, the semiconductor nanostructures 26 are formed of silicon, and the dummy semiconductor nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the stacking transistor. The upper semiconductor nanostructures 26U will provide channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming a dummy dielectric layer 36 on the semiconductor strips 28. The dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern the dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

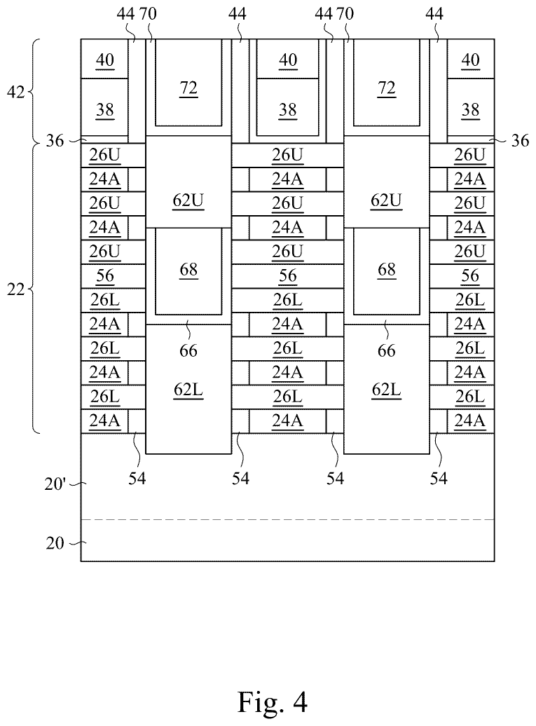

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower epitaxial source/drain regions 62L and upper epitaxial source/drain regions 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the second ILD 68.

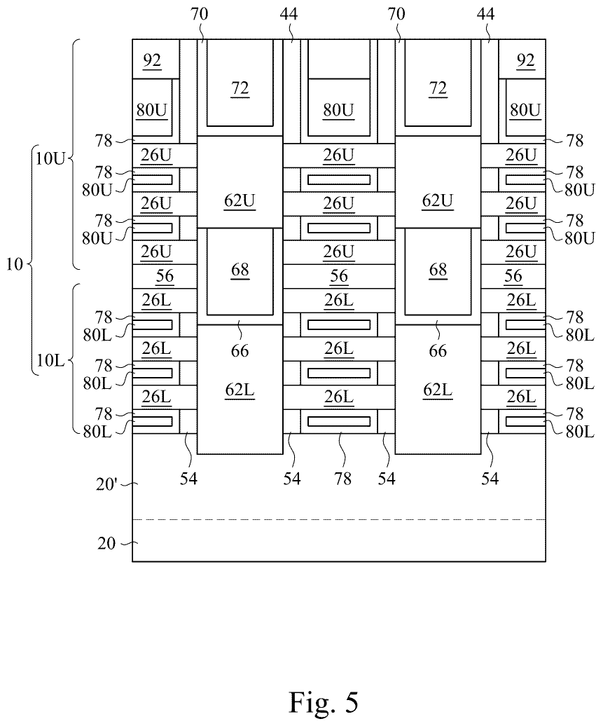

FIG. 5 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate stack 90” or a “gate structure 90” (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As also shown in FIG. 5, gate masks 92 are formed over the gate stacks 42. The formation process may include recessing gate structures 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

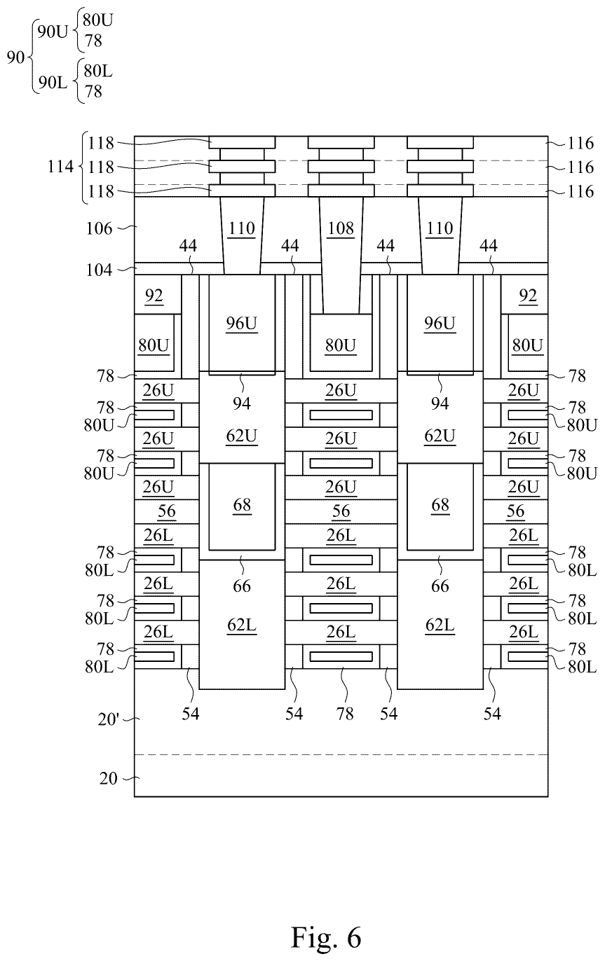

In FIG. 6, metal-semiconductor alloy regions 94 and source/drain contacts 96 are formed through the second ILD 72, in accordance with some embodiments. The source/drain contacts 96 include upper source/drain contacts 96U and lower source/drain contacts 96L that electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers. The conductive features 118 may include conductive lines and conductive vias, which may be formed using damascene processes or the like. The conductive features 118 may include diffusion barriers and copper-containing material over the diffusion barriers, in some cases. There may also be aluminum pads over and electrically connected to the conductive lines and vias. In some embodiments, wherein a thickness of a first dielectric layer 116 of a bottommost one of the plurality of dielectric layers 116 is less than a thickness of a first dielectric layer 116 of at least one of the plurality of dielectric layers 116 above the bottommost one of the plurality of dielectric layers 116. In some embodiments, wherein at least one of the conductive features 118 in a first dielectric layer 116 is thicker than at least one of the conductive features 118 in a second dielectric layer 116. The front-side interconnect structure 114 may have different numbers, configurations, or arrangements of features than shown.

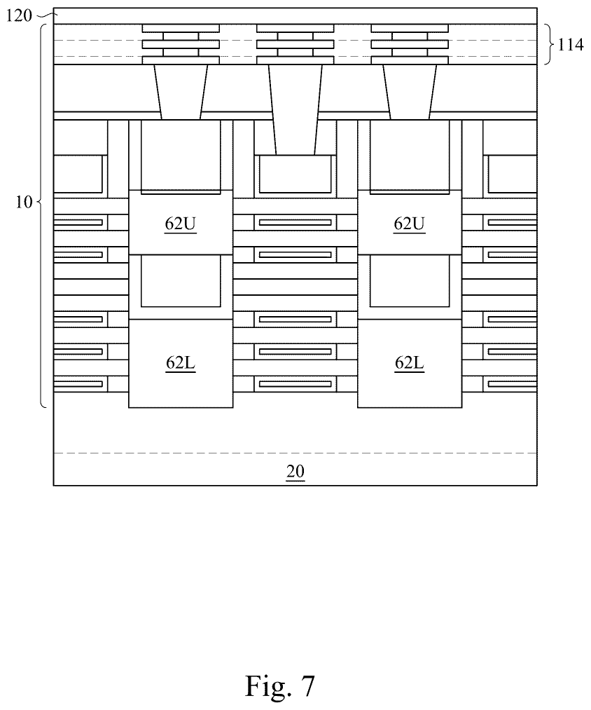

In FIG. 7, a bonding layer 120 is formed over the front-side interconnect structure 114, in accordance with some embodiments. The bonding layer 120 may be a material suitable for dielectric-to-dielectric bonding, such as silicon oxide, silicon oxynitride, or the like. The bonding layer 120 may be formed using a suitable technique, such as PVD, CVD, ALD, or the like. In some cases, the bonding layer 120 may comprise multiple layers of similar or different materials. In some cases, the perimeter of the structure (e.g., regions near the edges of the wafer, substrate 20, and/or features formed thereon) may be trimmed after forming the bonding layer 120.

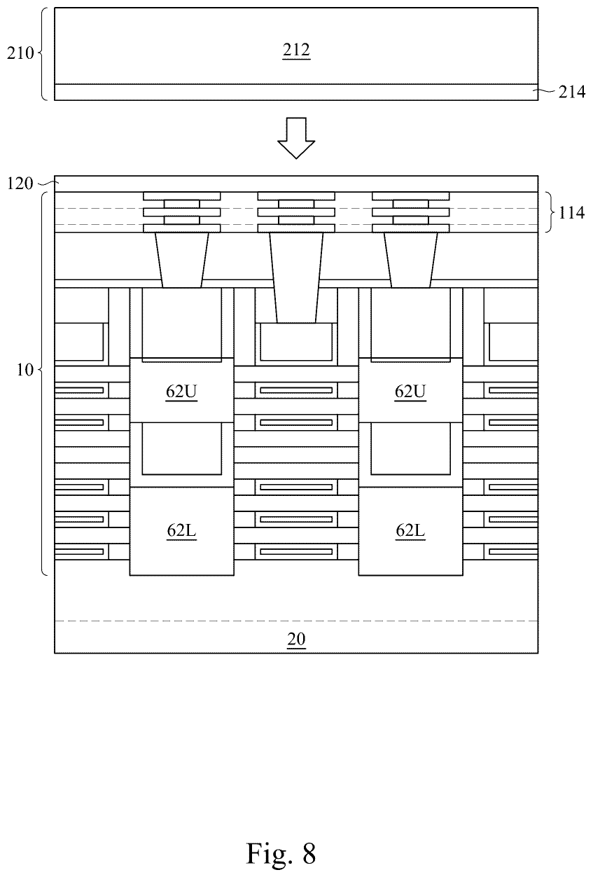

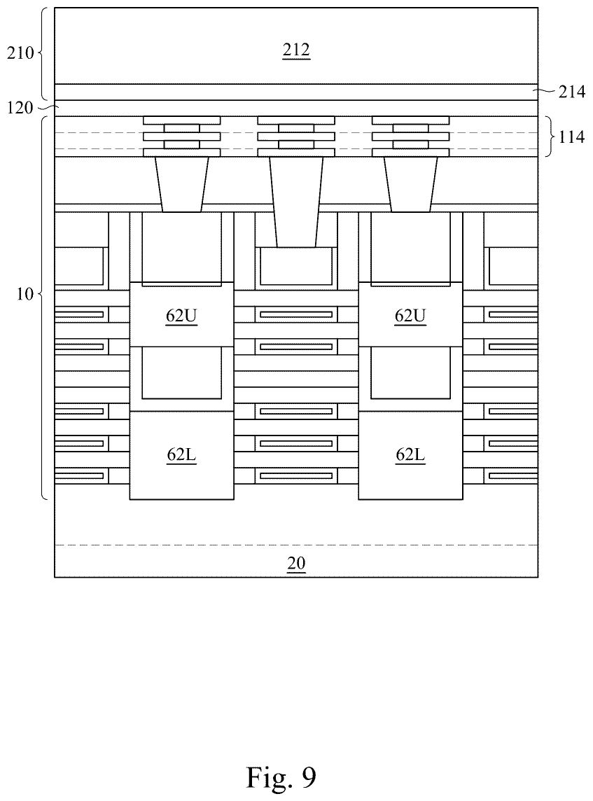

FIGS. 8 and 9 illustrate intermediate stages in the bonding of a carrier structure 210 to the stacking transistor 10, in accordance with some embodiments. FIG. 8 illustrates the carrier structure 210 prior to bonding, and FIG. 9 illustrates a bonded structure formed after bonding of the carrier structure 210. The carrier structure 210 may provide structural support and reduce warping during subsequent processing steps and in the completed device. In some cases, the carrier structure 210 includes a carrier bonding layer 214 on a side of a carrier substrate 212. The carrier substrate 212 may comprise a glass substrate, a ceramic substrate, a wafer (e.g., a silicon wafer), or the like. The carrier bonding layer 214 may be a material similar to that of the bonding layer 120, such as a material suitable for dielectric-to-dielectric bonding.

The carrier structure 210 may be bonded to the stacking transistor 10 by bonding the bonding layer 120 to the carrier bonding layer 214 using dielectric-to-dielectric bonding (e.g., direct bonding, fusion bonding, oxide bonding, or the like), in some embodiments. The dielectric-to-dielectric bonding process may further include applying a surface treatment to one or more of the bonding layer 120 and the carrier bonding layer 214, which can facilitate bonding of the bonding surfaces. The surface treatment may include a dry treatment, a wet treatment, a plasma treatment, exposure to an inert gas plasma, exposure to H₂, exposure to N₂, exposure to O₂, combinations thereof, or the like. For example, in some embodiments, the surface treatment comprises a plasma treatment followed by a cleaning process (e.g., a rinse with deionized water or the like) that may be applied to one or more of the bonding surfaces. In some cases, the plasma treatment forms hydroxyl groups (—OH groups) on the bonding surfaces, which may be bonded to water molecules by hydrogen bonds. In other embodiments, the surface treatment may comprise other types of treatments.

The carrier bonding layer 214 of the carrier structure 210 may be aligned with the bonding layer 120, and the bonding surfaces may be pressed against each other to initiate a pre-bonding process. During the pre-bonding process, hydrogen bonds may be formed between the water molecules on the surface of the bonding layer 120 and the water molecules on the surface of the carrier bonding layer 214. An annealing process may then be performed to remove water molecules from the bonding surfaces. The annealing process may induce the formation of covalent bonds between silicon atoms and oxygen atoms on the bonding surfaces, thus bonding the surface of the bonding layer 120 to the carrier bonding layer 214 to form a bonded structure. This is an example, and other dielectric-to-dielectric bonding processes are possible. In some embodiments, the resulting bonded structure is subsequently baked, annealed, pressed, or otherwise treated to strengthen or finalize the bond.

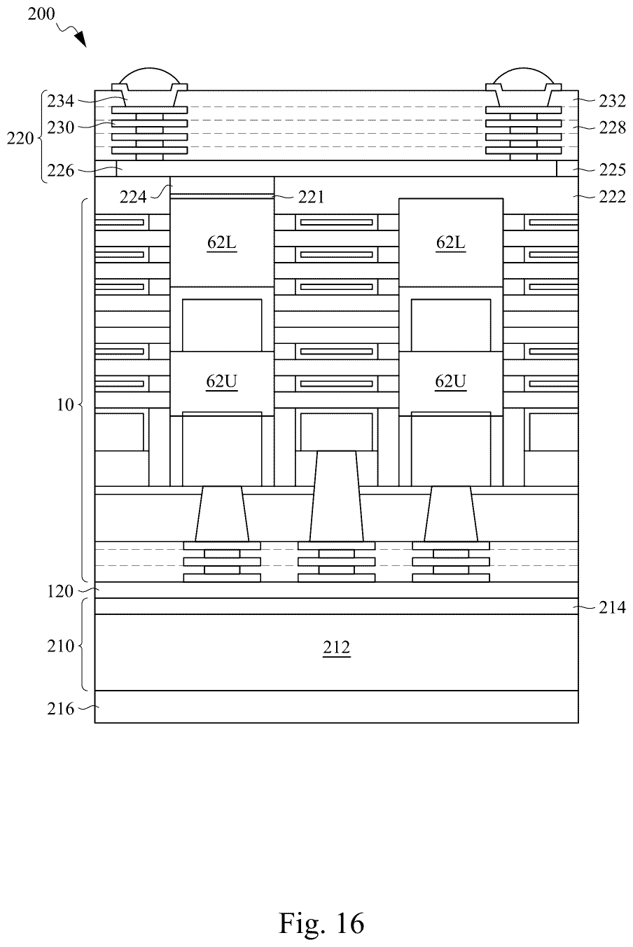

In some embodiments, one or more warpage control layers may be formed on the carrier structure 210 to provide additional structural support and rigidity. The use of warpage control layer(s) as described herein can reduce warpage or stress of the structure during subsequent processing. For example, the use of warpage control layer(s) can reduce warpage or stress during subsequent formation of a back-side interconnect structure 220 (see FIG. 16) or the like. In some cases, the use of warpage control layer(s) as described herein can reduce wafer warpage by as much as 50 μm, though other amounts are possible. In this manner, warpage can be controlled and device processing, reliability, and yield can be improved. While the embodiments described below are in the context of a stacking transistor 10, the warpage control layers as described herein may be utilized in any suitable device or structure.

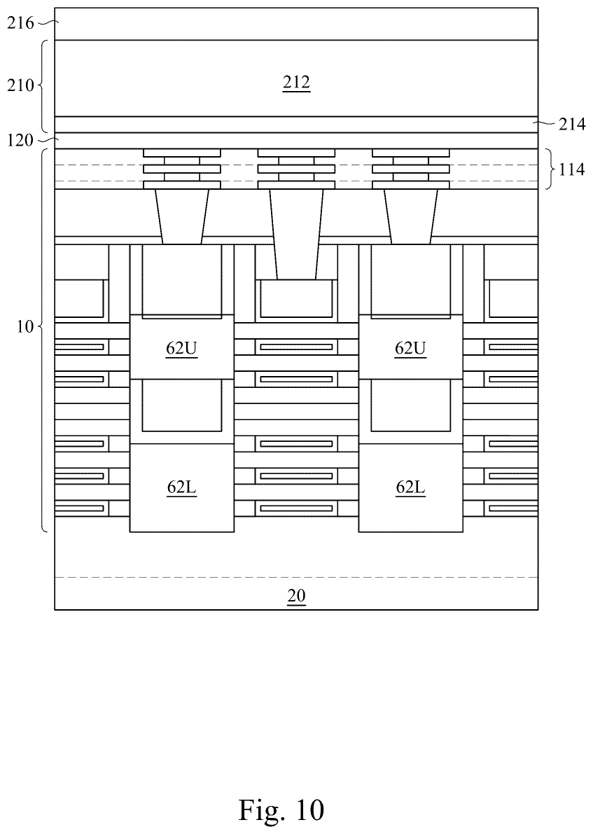

FIG. 10 illustrates an embodiment in which a warpage control layer 216 is formed on the carrier structure 210 after bonding the carrier structure 210. In other words, the warpage control layer 216 is formed on the bonded structure. The warpage control layer 216 may be formed on a surface of the carrier substrate 212 (e.g., an outer surface or a back-side surface of the carrier substrate 212), in some embodiments. In some embodiments, the warpage control layer 216 comprises a dielectric layer or an insulating layer that exhibits tensile stress (e.g., on the carrier substrate 212, on the partially-manufactured structure, and/or on the semiconductor die 200 (see FIG. 16)). For example, the warpage control layer 216 may exhibit tensile stress in the range of about 0.1 GPa to about 1.5 GPa, though other amounts are possible. In some embodiments, the warpage control layer 216 may comprise a layer of a material such as silicon nitride, silicon carbonitride, aluminum nitride, boron nitride, or the like, though other materials are possible. The warpage control layer 216 may be deposited on the carrier structure 210 using a suitable technique, such as CVD, PVD, ALD, PECVD, plasma-enhanced ALD (PEALD), or the like. In some embodiments, the warpage control layer 216 may have a thickness in the range of about 100 Å to about 5000 Å, though other thicknesses are possible. In some cases, a thickness of less than about 100 Å may provide insufficient warpage control. In some cases, a thickness of greater than about 5000 Å may cause reduced adhesion of the warpage control layer 216 to the carrier structure 210 or may cause cracking of the warpage control layer 216. In some cases, the warpage control layer 216 may be considered a “tensile stress layer” or the like.

As an example, in some embodiments, the warpage control layer 216 may be a layer of silicon nitride. The layer of silicon nitride may be formed using PVD, CVD, PECVD with silane (SiH₄), nitrogen (N₂), and ammonia (NH₃) as precursors, PEALD with dichlorosilane (DCS), nitrogen (N₂), and ammonia (NH₃), or using another suitable technique. In some embodiments, the silicon nitride may be formed using a process temperature in the range of about 200° C. to about 500° C., though other temperatures are possible. In some cases, forming silicon nitride at a process temperature less than about 200° C. may result in out-gassing, poorer quality material, and larger stress variation. In some cases, forming silicon nitride at a process temperature greater than about 500° C. may cause metal diffusion or may affect characteristics of work function layers. In some cases, the warpage control layer 216 may comprise a layer of silicon nitride having a tensile stress in the range of about 0.1 GPa to about 1.5 GPa, though other amounts are possible. This is an example, and other materials are possible.

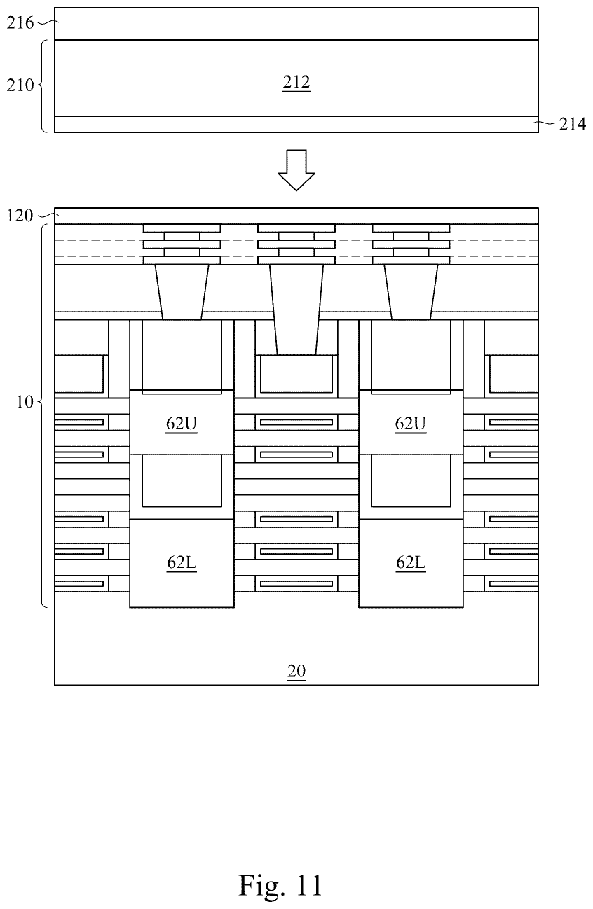

FIG. 11 illustrates an intermediate stage in the bonding of a carrier structure 210 to the stacking transistor 10, in accordance with some embodiments. FIG. 11 illustrates the structure prior to bonding of the carrier structure 210. The carrier structure 210 is similar to that described previously for FIGS. 8 and 9, except that a warpage control layer 216 is formed on the carrier structure 210 before bonding the carrier structure 210. After bonding the carrier structure 210, the resulting bonded structure may be similar to that shown in FIG. 10. The warpage control layer 216 of FIG. 11 may be similar to the warpage control layer 216 described previously, and may be formed using similar techniques. For example, the warpage control layer 216 may be a layer of silicon nitride deposited on the carrier structure 210 prior to bonding, though other materials are possible. The carrier structure 210 may be bonded to the stacking transistor 10 using similar techniques as described for FIGS. 8-9. For example, a carrier bonding layer 214 of the carrier structure 210 may be bonded to a bonding layer 120 over the stacking transistor 10 using a dielectric-to-dielectric bonding process. In some cases, forming the warpage control layer 216 before bonding the carrier structure 210 can allow for more flexibility in the deposition techniques used to form the warpage control layer 216. For example, the stacking transistor 10 is not exposed to the process temperatures of the formation of the warpage control layer 216 if the warpage control layer 216 is deposited before bonding the carrier structure 210.

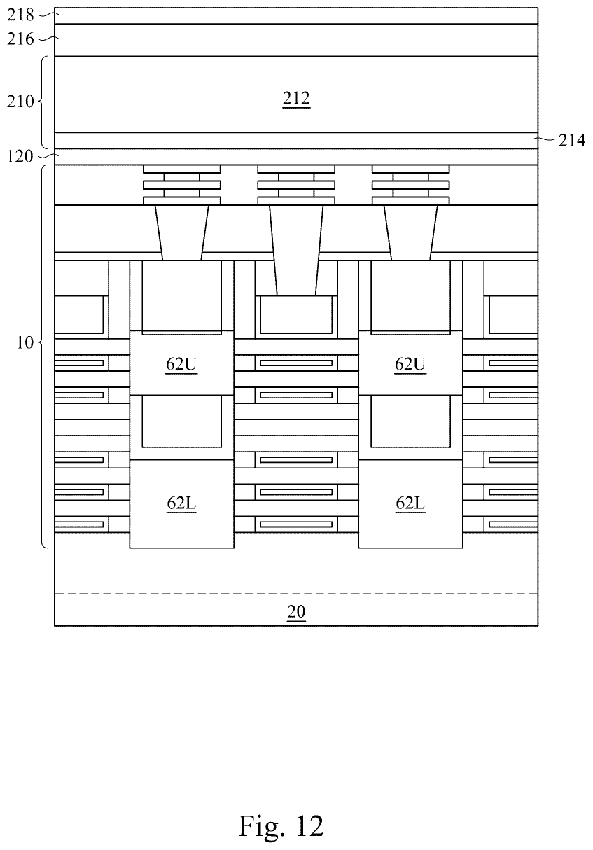

FIG. 12 illustrates an additional warpage control layer 218 formed on the warpage control layer 216, in accordance with some embodiments. FIG. 12 illustrates a single additional warpage control layer 218 formed on a bonded structure similar to that of FIG. 10, but multiple additional warpage control layers 218 are possible in other embodiments. The one or more additional warpage control layers 218 may be formed before or after bonding of the carrier structure 210. In some cases, the additional warpage control layer 218 is considered to be part of the warpage control layer 216. In some cases, the additional warpage control layer 218 may provide additional structural support, additional rigidity, further warpage reduction, and/or protection for the device.

The additional warpage control layer 218 may be a different material than the warpage control layer 216, or may be a similar material with different characteristics. The additional warpage control layer 218 may comprise one or more materials such as silicon oxide, silicon oxynitride, silicon, amorphous silicon, the like, or a combination thereof. For example, the additional warpage control layer 218 may be a layer of silicon oxide or amorphous silicon over a warpage control layer 216 of silicon nitride, in some embodiments. In some embodiments, an additional warpage control layer 218 of silicon over a warpage control layer 216 of silicon nitride may form as amorphous silicon. The additional warpage control layer 218 may be formed using a suitable technique, such as PVD, CVD, FCVD, ALD, or the like. The additional warpage control layer 218 may have a thickness in the range of about 500 Å to about 5000 Å, though other thicknesses are possible. In some cases, for embodiments in which the warpage control layer 216 is a relatively lower conductivity material such as silicon nitride, using an additional warpage control layer 218 of a relatively higher conductivity material such as silicon may provide improved electrical discharge or grounding for the device. In some cases, for embodiments in which the warpage control layer 216 is relatively hard material such as silicon nitride, using an additional warpage control layer 218 of a relatively softer material such as silicon oxide, silicon, or amorphous silicon may protect processing components from scratching or damage from the warpage control layer 216. These are examples, and other materials or combinations of materials are possible.

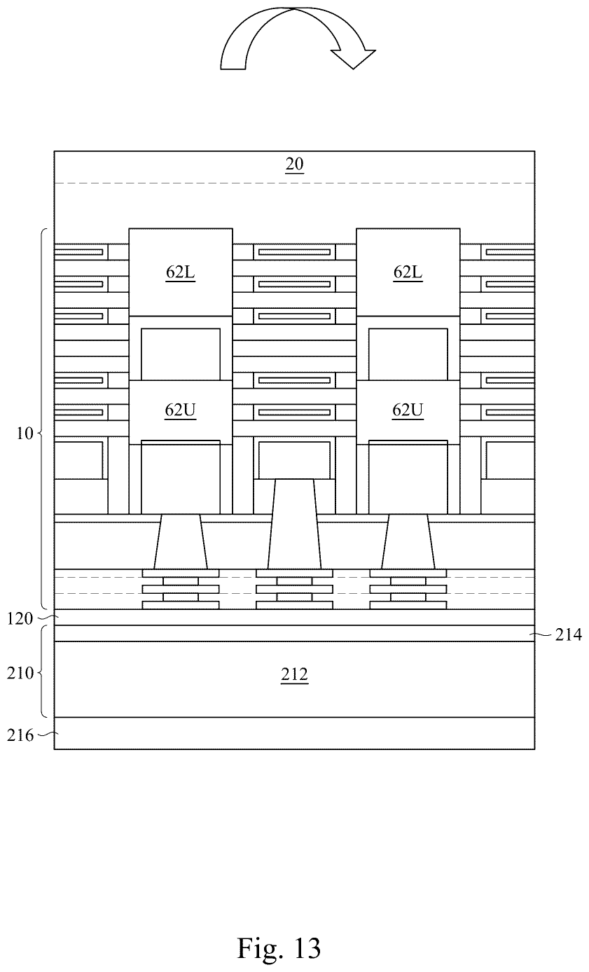

FIGS. 13 through 16 illustrate intermediate stages in the formation of a back-side interconnect structure 220 (see FIG. 16), in accordance with some embodiments. The back-side interconnect structure 220 is formed after bonding the carrier structure 210 and forming the warpage control layer 216, in some embodiments. As described below, the back-side interconnect structure 220 may include a power rail, in some embodiments. In some cases, forming a warpage control layer 216 (which may include an additional warpage control layer 218) may reduce warpage or stress during formation of the back-side interconnect structure 220 and may reduce warpage or stress of the device after formation of the back-side interconnect structure 220. For example, a warpage control layer 216 can reduce warpage from high tensile stress generated by the presence of multiple metal layers in the back-side interconnect structure 220. In some cases, the use of a warpage control layer 216 as described herein can reduce warpage due to the formation of a power rail on the back-side of the device.

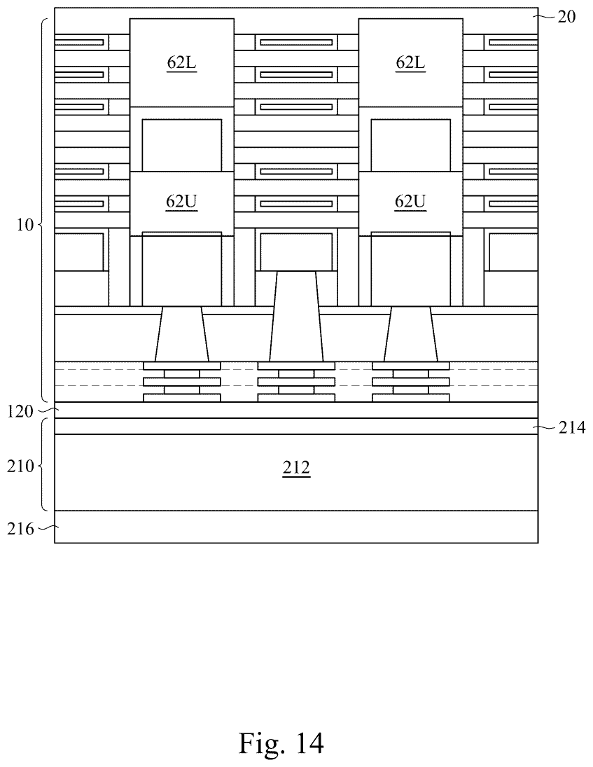

In FIG. 13, the bonded structure of FIG. 10 is flipped upside-down, such that the back-side of the substrate 20 faces upwards. In FIG. 14, a thinning process may be applied to the back-side of the substrate 20. The thinning process may comprise a planarization process (e.g., a mechanical grinding, a CMP process, or the like), an etch-back process, a combination thereof, or the like. In some embodiments, a portion of the substrate 20 may remain over the lower gate structures 90L, the lower semiconductor nanostructures 26L, and/or the lower epitaxial source/drain regions 62L after the thinning process. In some embodiments, surfaces of the substrate 20, the STI regions 32, and the fins 20′ (not shown in the cross-sections of FIG. 13-16) may be approximately level or coplanar following the thinning process. In other embodiments, portions of the lower epitaxial source/drain regions 62L may be exposed by the thinning process.

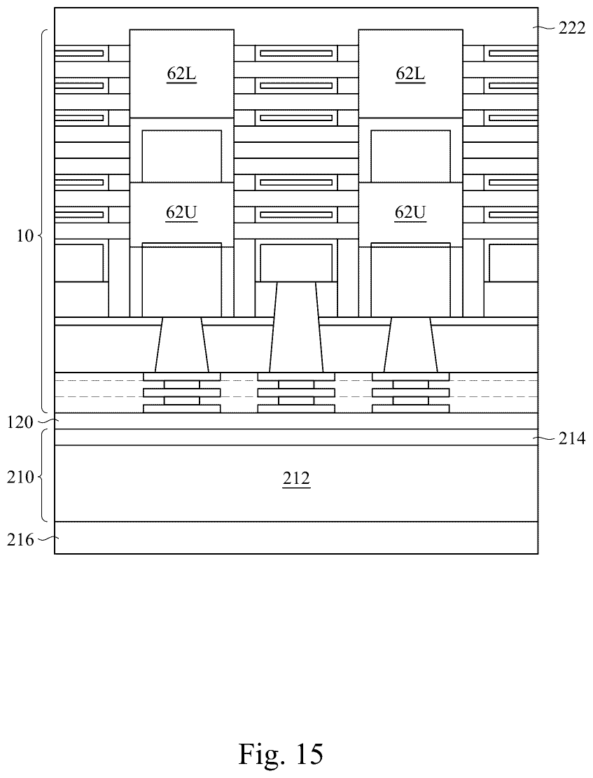

In FIG. 15, remaining portions of the fins 20′ and the substrate 20 are removed and replaced with an insulating layer 222. The fins 20′ and the substrate 20 may be etched using a suitable etching process, such as an isotropic etching process (e.g., a wet etching process), an anisotropic etching process (e.g., a dry etching process), or the like. The etching process may be one that is selective to the material of the fins 20′ and the substrate 20. For example, the etching process may etch the material of the fins 20′ and the substrate 20 at a faster rate than the material of the STI regions 32, the lower gate structures 90L, the lower epitaxial source/drain regions 62L, and/or the inner spacers 54. Removing the fins 20′ and the substrate 20 exposes back-side surfaces of the stacking transistor 10. For example, after etching the fins 20′ and the substrate 20, surfaces of the STI regions 32, the lower gate structures 90L, the lower epitaxial source/drain regions 62L, and/or the inner spacers 54 may be exposed.

The insulating layer 222 is then deposited on the back-side of the stacking transistor 10. The insulating layer 222 may physically contact surfaces of the STI regions 32, the lower gate structures 90L, the lower epitaxial source/drain regions 62L, and/or the inner spacers 54. In some embodiments, the insulating layer 222 may be similar to the second ILD 72, the third ILD 106, or the dielectric layers 116, and may be formed using similar techniques. In some embodiments, the insulating layer 222 is thinned using a planarization process or the like.

In FIG. 16, the back-side interconnect structure 220 is formed over the insulating layer 222, in accordance with some embodiments. In some embodiments, the insulating layer 222 may be recessed to expose portions of the lower epitaxial source/drain regions 62L. The insulating layer 222 may be recessed using suitable photolithography and etching techniques. Metal-semiconductor alloy regions 221 may be formed on surfaces of the lower epitaxial source/drain regions 62L exposed by the recesses in the insulating layer 222. The metal-semiconductor alloy regions 221 may be similar to the metal-semiconductor alloy regions 94 described previously, and may be formed using similar materials or techniques. Back-side vias 224 may then be formed on the metal-semiconductor alloy regions 221 in the recesses in the insulating layer 222. The back-side vias 224 make electrical connection to the lower epitaxial source/drain regions 62L through the metal-semiconductor alloy regions 221. Accordingly, the back-side vias 224 may be considered source/drain contacts, in some cases. The back-side vias 224 may be similar to the source/drain contacts 96 described previously, and may be formed using similar materials or techniques.

Conductive lines 226 and a dielectric layer 225 are formed over the insulating layer 222, and the back-side vias 224. The dielectric layer 225 may be similar to the insulating layer 222, and may be formed using similar materials or techniques. The conductive lines 226 are formed in the dielectric layer 225. Forming the conductive lines 226 may include patterning recesses in the dielectric layer 225 using a combination of photolithography and etching processes, for example. A pattern of the recesses in the dielectric layer 225 may correspond to a pattern of the conductive lines 226. The conductive lines 226 are then formed by depositing a conductive material in the recesses. In some embodiments, the conductive lines 226 comprise a metal layer, which may be a single layer or a composite layer comprising a plurality of sub-layers formed of different materials. In some embodiments, the conductive lines 226 comprise copper, aluminum, cobalt, tungsten, titanium, tantalum, ruthenium, or the like. An optional diffusion barrier and/or optional adhesion layer may be deposited prior to filling the recesses with the conductive material. Suitable materials for the barrier layer/adhesion layer include titanium, titanium nitride, titanium oxide, tantalum, tantalum nitride, titanium oxide, or the like. The conductive lines 226 may be formed using, for example, CVD, ALD, PVD, plating or the like. The conductive lines 226 are physically and electrically coupled to the epitaxial source/drain regions 62 through the back-side vias 224 and the metal-semiconductor alloy regions 221. A planarization process (e.g., CMP, grinding, an etch-back, or the like) may be performed to remove excess portions of the conductive lines 226 formed over the dielectric layer 225.

In some embodiments, the conductive lines 226 are power rails, which are conductive lines that electrically connect the epitaxial source/drain regions 62 to a reference voltage (e.g., an electrical ground), a power supply (e.g., a supply voltage), or the like. By placing power rails on a back-side of the resulting device rather than on a front-side of the device, advantages may be achieved. For example, a gate density of the stacking transistors and/or an interconnect density of the front-side interconnect structure 114 may be increased. Further, the back-side of the device may accommodate wider power rails, reducing resistance and increasing efficiency of power delivery to the stacking transistors. For example, in some embodiments, a width of the conductive lines 226 may be at least twice a width of first level conductive lines (e.g., first conductive features 118) of the front-side interconnect structure 114.

Other features of the back-side interconnect structure 220 are formed over the dielectric layer 225 and the conductive lines 226. In some embodiments, the back-side interconnect structure 220 includes dielectric layers 228 and layers of conductive features 230 in the dielectric layers 228. The conductive features 230 may include conductive lines, conductive vias, or the like. The conductive features 230 may further be patterned to include one or more embedded passive devices such as resistors, capacitors, inductors, or the like. The embedded passive devices may be integrated with the conductive lines 226 (e.g., the power rails) to provide circuits (e.g., power circuits) on the back-side of the stacking transistors. The back-side interconnect structure 220 may comprise materials and be formed using processes the same as or similar to those used for the front-side interconnect structure 114. For example, the dielectric layers 228 may be formed of similar materials using similar processes as the dielectric layers 116, and the conductive features 230 may be formed of similar materials using similar processes as the conductive features 118. Other materials or formation processes are possible.

In some embodiments, a passivation layer 232, UBMs 234, and external connectors 236 are formed over the back-side interconnect structure 220. The passivation layer 232 may comprise polymers such as PBO, polyimide, BCB, or the like. Alternatively, the passivation layer 232 may include non-organic dielectric materials such as silicon oxide, silicon nitride, silicon carbide, silicon oxynitride, or the like. The passivation layer 232 may be deposited by, for example, CVD, PVD, ALD, or the like. The UBMs 234 are formed through the passivation layer 232 to the conductive lines 230 in the back-side interconnect structure 220, and the external connectors 236 are formed on the UBMs 234. The UBMs 234 may comprise one or more layers of copper, nickel, gold, or the like, which are formed by a plating process, or the like. The external connectors 236 (e.g., solder balls, solder bumps, or the like) are formed on the UBMs 234. The formation of the external connectors 236 may include placing solder balls on exposed portions of the UBMs 234 and reflowing the solder balls. In some embodiments, the formation of the external connectors 236 includes performing a plating step to form solder regions over the topmost conductive lines 230 and then reflowing the solder regions. The UBMs 234 and the external connectors 236 may be used to provide input/output connections to other electrical components, such as other device dies, redistribution structures, interposers, printed circuit boards (PCBs), motherboards, or the like. The UBMs 234 and the external connectors 236 may also be referred to as back-side input/output pads that may provide signal, supply voltage, and/or ground connections to the stacking transistors described above.

Subsequently, a singulation process may be applied along scribe lines (not illustrated) to separate the structure into individual semiconductor dies 200 (e.g., integrated circuit dies, chips, or the like). In this manner, an individual semiconductor die 200 having a front-side interconnect structure 114, a back-side interconnect structure 220, stacking transistors 10 and/or other devices, a carrier structure 210, and a warpage control layer 216 may be manufactured. In some cases, the warpage control layer 216 as described herein can reduce warpage of the singulated dies.

The embodiments of the present disclosure have some advantages. By forming a warpage control layer on a carrier substrate, warpage of a wafer, device, die, or the like can be reduced. A warpage control layer may be a single layer of material or may be a multi-layer structure of different materials. The warpage control layer can be formed on a carrier substrate either before attaching the carrier substrate to the device structure or after attaching the carrier substrate to the device structure. The warpage control layer can reduce wafer warpage by as much as about 50 μm, in some cases. In some cases, the use of a warpage control layer as described herein can reduce warpage resulting from stresses imparted by back end of line (BEOL) interconnect layers, such as those in a front-side interconnect structure or a back-side interconnect structure. In some cases, the use of a warpage control layer as described herein can reduce warpage resulting from stresses resulting from the formation of nanostructure-FETs, stacking transistors, or the like. In some cases, the use of a warpage control layer as described herein can reduce warpage of wafers in which a power rail or the like is formed. In this manner, the use of a warpage control layer can improve yield and reliability.

In an embodiment, a method includes forming nanostructures over a semiconductor substrate; forming a front-side interconnect structure over a front-side of the nanostructures; directly bonding a first side of a carrier substrate to the front-side interconnect structure using a dielectric-to-dielectric bonding process; depositing a dielectric layer on a second side of the carrier substrate; and forming a back-side interconnect structure over a back-side of the nanostructures. In an embodiment, the dielectric layer is formed before bonding the first side of the carrier substrate to the front-side interconnect structure. In an embodiment, the back-side interconnect structure is formed after forming the dielectric layer. In an embodiment, the dielectric layer provides a tensile stress in the range of 0.1 GPa to 1.5 GPa. In an embodiment, the dielectric layer has a thickness in the range of 100 Å to 5000 Å. In an embodiment, the back-side interconnect structure is formed after depositing the dielectric layer. In an embodiment, the dielectric layer includes a layer of silicon nitride. In an embodiment, the method includes forming a layer of amorphous silicon on the layer of silicon nitride.

In an embodiment, a method includes forming stacking transistors on a first substrate; forming a first interconnect structure on the stacking transistors; depositing a first bonding layer on the first interconnect structure; forming a carrier structure including depositing a second bonding layer on a second substrate; depositing an insulating layer on the second substrate opposite the second bonding layer, wherein the insulating layer exhibits tensile stress on the second substrate; after forming the carrier structure, bonding the second bonding layer to the first bonding layer using a direct bonding process; and after bonding the second bonding layer to the first bonding layer, forming a second interconnect structure on the stacking transistor opposite the first interconnect structure, wherein the second interconnect structure is electrically connected to the stacking transistors. In an embodiment, the method includes removing the first substrate before forming the second interconnect structure. In an embodiment, the insulating layer includes amorphous silicon, silicon carbonitride, aluminum nitride, or boron nitride. In an embodiment, the second interconnect structure includes a power rail electrically connected to the stacking transistors. In an embodiment, depositing the insulating layer includes depositing a layer of silicon nitride using a process temperature in the range of 200° C. to 500° C. In an embodiment, the method includes depositing a layer of silicon oxide on the insulating layer.

In an embodiment, a device includes a stacking transistor; a first interconnect structure over and connected to a front-side of the stacking transistor; a second interconnect structure over and connected to a back-side of the stacking transistor; and a support structure attached to the first interconnect structure, wherein the support structure includes a tensile stress layer on a support substrate. In an embodiment, the tensile stress layer comprises at least one of silicon nitride, silicon carbonitride, aluminum nitride, or boron nitride. In an embodiment, the support substrate includes a silicon wafer. In an embodiment, the second interconnect structure includes a power supply line or electrical ground line electrically connected to a first source/drain region of the stacking transistor. In an embodiment, the tensile stress layer has a tensile stress in the range of 0.1 GPa to 1.5 GPa. In an embodiment, the support substrate is sandwiched between the tensile stress layer and the first interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of nanostructures over a semiconductor substrate;
forming a front-side interconnect structure over a front-side of the plurality of nanostructures;
directly bonding a first side of a carrier substrate to the front-side interconnect structure using a dielectric-to-dielectric bonding process;
depositing a dielectric layer on a second side of the carrier substrate; and
forming a back-side interconnect structure over a back-side of the plurality of nanostructures.

2. The method of claim 1, wherein the dielectric layer is formed before bonding the first side of the carrier substrate to the front-side interconnect structure.

3. The method of claim 1, wherein the back-side interconnect structure is formed after forming the dielectric layer.

4. The method of claim 1, wherein the dielectric layer provides a tensile stress in the range of 0.1 GPa to 1.5 GPa.

5. The method of claim 1, wherein the dielectric layer has a thickness in the range of 100 Å to 5000 Å.

6. The method of claim 1, wherein the back-side interconnect structure is formed after depositing the dielectric layer.

7. The method of claim 1, wherein the dielectric layer comprises a layer of silicon nitride.

8. The method of claim 7 further comprising forming a layer of amorphous silicon on the layer of silicon nitride.

9. A method comprising:
forming a plurality of stacking transistors on a first substrate;
forming a first interconnect structure on the plurality of stacking transistors;
depositing a first bonding layer on the first interconnect structure;
forming a carrier structure comprising:
depositing a second bonding layer on a second substrate;
depositing an insulating layer on the second substrate opposite the second bonding layer, wherein the insulating layer exhibits tensile stress on the second substrate;
after forming the carrier structure, bonding the second bonding layer to the first bonding layer using a direct bonding process; and
after bonding the second bonding layer to the first bonding layer, forming a second interconnect structure on the plurality of stacking transistor opposite the first interconnect structure, wherein the second interconnect structure is electrically connected to the plurality of stacking transistors.

10. The method of claim 9 further comprising removing the first substrate before forming the second interconnect structure.

11. The method of claim 9, wherein the insulating layer comprises amorphous silicon, silicon carbonitride, aluminum nitride, or boron nitride.

12. The method of claim 9, wherein the second interconnect structure comprises a power rail electrically connected to the plurality of stacking transistors.

13. The method of claim 9, wherein depositing the insulating layer comprises depositing a layer of silicon nitride using a process temperature in the range of 200° C. to 500° C.

14. The method of claim 9 further comprising depositing a layer of silicon oxide on the insulating layer.

15. A device comprising:
a stacking transistor;
a first interconnect structure over and connected to a front-side of the stacking transistor;
a second interconnect structure over and connected to a back-side of the stacking transistor; and
a support structure attached to the first interconnect structure, wherein the support structure comprises a tensile stress layer on a support substrate.

16. The device of claim 15, wherein the tensile stress layer comprises at least one of silicon nitride, silicon carbonitride, aluminum nitride, or boron nitride.

17. The device of claim 15, wherein the support substrate comprises a silicon wafer.

18. The device of claim 15, wherein the second interconnect structure comprises a power supply line or electrical ground line electrically connected to a first source/drain region of the stacking transistor.

19. The device of claim 15, wherein the tensile stress layer has a tensile stress in the range of 0.1 GPa to 1.5 GPa.

20. The device of claim 15, wherein the support substrate is sandwiched between the tensile stress layer and the first interconnect structure.
